(19) United States
(12) Patent Application Publication
(10) Pub. No.: US 2024/0243021 A1
(43) Pub. Date: Jul. 18, 2024

(54) PACKAGE CARRIER AND MANUFACTURING METHOD THEREOF AND CHIP PACKAGE STRUCTURE

(71) Applicant: Chung W. Ho, Taipei City (TW)

(72) Inventor: Chung W. Ho, Taipei City (TW)

(21) Appl. No.: 18/413,041

(22) Filed: Jan. 16, 2024

(30) Foreign Application Priority Data
Jan. 17, 2023 (TW) 112102007

(51) Int. Cl. H01L 23/13; H01L 23/00; H01L 23/498

(52) U.S. Cl. CPC H01L 23/13; H01L 23/49816; H01L 23/49838; H01L 24/13; H01L 24/29; H01L 2224/13009; H01L 2224/13025; H01L 2224/29009; H01L 2224/29025; H01L 2924/15153; H01L 2924/15311

(57) ABSTRACT

A package carrier includes a signal board, a power board and a connection layer. The signal board includes a plurality of first circuits. The power board includes a plurality of second circuits. A line width of each of the first circuits is less than a line width of each of the second circuits, and a first thickness of the signal board is less than a second thickness of the power board. The connection layer is disposed between the signal board and the power board, wherein the power board is electrically connected to the signal board through the connection layer.

### CROSS-REFERENCE TO RELATED APPLICATION

This application claims the priority benefit of Taiwan application serial no. 112102007, filed on Jan. 17, 2023. The entirety of the above-mentioned patent application is hereby incorporated by reference herein and made a part of specification.

### BACKGROUND

### Field of the Disclosure

The present disclosure relates to a carrier structure, a manufacturing method thereof, and a package structure, and in particular, to a package carrier, a manufacturing method thereof, and a semiconductor chip substrate package structure.

### Description of Related Art

In the existing package carrier, the signal distribution and the power distribution are presented in a mixed manner in the same circuits structure. The above-mentioned manufacturing method unnecessarily increase the thicknesses and of the metal and the dielectric layers in the signal layers. The density of the signal layer is suffered as a result. In addition, the metal thicknesses of power layers should be much greater than those signal layers. If the power layer is manufactured through the same process as the signal layer, the cost will increase due to the use of laser drilling to make conductive vias.

### SUMMARY OF THE DISCLOSURE

The present disclosure provides a package carrier that may separate signals from power, thereby improving the efficiency and design for both signal layers and power layers.

The present disclosure further provides a method for manufacturing a package carrier, which is adopted to manufacture the package carrier. The manufacturing process is simple and may effectively reduce the manufacturing cost.

The present disclosure further provides a chip package structure, which includes the package carrier and may have a better yield and quality.

The package carrier of the present disclosure includes a signal board, a power board and a connection layer. The signal board includes a plurality of first circuits. The power board includes a plurality of second circuits. The line width of each first circuit is less than the line width of each second circuit, and a first thickness of the signal board is less than a second thickness of the power board. The connection layer is disposed between the signal board and the power board, and the power board is electrically connected to the signal board through the connection layer.

In an embodiment of the present disclosure, the signal board has a set of stacked vias, which penetrates the signal board and is connected to the connection layer.

In an embodiment of the present disclosure, the signal board further includes a plurality of connection circuits, respectively connecting two adjacent first circuits.

In an embodiment of the present disclosure, the package carrier further includes a plurality of capacitors, which are embedded in the power board and are electrically connected to the power board.

In an embodiment of the present disclosure, the thickness of the power board is at least four times the thickness of the signal board or more.

In an embodiment of the present disclosure, the connection layer includes an insulating layer and a plurality of conductive bumps passing through the insulating layer. The second circuit of the power board is electrically connected to the first circuit of the signal board through the conductive bump.

The manufacturing method of the package carrier of the present disclosure includes the following steps. A substrate is provided. The substrate includes a base, a stainless steel layer and a metal layer. The stainless steel layer is located on the base and conformally covers the base. The metal layer is formed on and conformally covers the stainless steel layer. Two signal boards are formed on opposite sides of the substrate, and each signal board includes a plurality of first circuits. Two power boards are provided. Each power board includes a plurality of second circuits. Two connection layers are provided between each signal board and each power board. The two power boards and the two connection layers are laminated onto the substrate, wherein each power board is electrically connected to each signal board through each connection layer. The line width of each first circuit is less than the line width of each second circuit. A first thickness of the signal board is less than a second thickness of the power board. The substrate and the two signal boards are separated to form two package carriers that are separated from each other. Each package carrier includes one of two signal boards, one of two power boards, and one of two connection layers.

In an embodiment of the present disclosure, the base of the substrate includes two protrusions. The two protrusions are respectively located on opposite sides of the base. When the substrate and the two signal boards are separated from each other, a cavity that penetrates through each signal board is formed. The cavity exposes a portion of the connection layer.

In an embodiment of the present disclosure, the signal board further includes a plurality of connection circuits which respectively connect two adjacent first circuits.

In an embodiment of the present disclosure, the manufacturing method of the package carrier further includes forming a plurality of capacitors embedded in each power board before laminating the two power boards and the two connection layers onto the substrate, and the plurality of capacitors are electrically connected to each corresponding power board.

In an embodiment of the present disclosure, the thickness of the power board is at least four times the thickness of the signal board or more.

In an embodiment of the present disclosure, the connection layer includes an insulating layer and a plurality of conductive bumps passing through the insulating layer. The second circuit of the power board is electrically connected to the first circuit of the signal board through the conductive bumps.

In an embodiment of the present disclosure, each of the connection layers includes an insulating layer, a plurality of conductive bumps passing through the insulating layer, and a release film. The second circuit of the power board is electrically connected to the first circuit of the signal board through the conductive bumps. The position of the release film respectively corresponds to the position of each protrusion. When the substrate and the two signal boards are separated from each other, the cavity exposes the release film of each connection layer.

The chip package structure of the present disclosure includes a package carrier and at least one chip. The package carrier includes a signal board, a power board and a connection layer. The signal board includes a plurality of first circuits. The power board includes a plurality of second circuits. The line width of each first circuit is less than the line width of each second circuit, and a first thickness of the signal board is less than a second thickness of the power board. The connection layer is disposed between the signal board and the power board. The power board is electrically connected to the signal board through the connection layer, which may effectively improve the performance and stability of the power supply. The chip is disposed on the signal board and is electrically connected to the first circuit.

In an embodiment of the present disclosure, the signal board has a set of stacked vias, which penetrates the signal board and is connected to the connection layer.

In an embodiment of the present disclosure, the at least one chip includes a first chip and a second chip. The first chip is disposed in the set of stacked vias and is electrically connected to the first circuit through a plurality of wires. The second chip is disposed on the signal board and is electrically connected to the first circuit through a plurality of solder balls.

In an embodiment of the present disclosure, the at least one chip includes a first chip and two second chips. The package carrier further includes an outer circuit layer. The first chip is disposed in the set of stacked vias, and the outer circuit layer covers the first chip and the signal board. The two second chips are disposed on the signal board and are electrically connected to the first chip through a plurality of solder balls.

In an embodiment of the present disclosure, the signal board further includes a plurality of connection circuits which respectively connect two adjacent first circuits.

In an embodiment of the present disclosure, the at least one chip is disposed on the signal board and is electrically connected to the first circuit through a plurality of solder balls.

In an embodiment of the present disclosure, the thickness of the power board is at least four times the thickness of the signal board or more.

In an embodiment of the present disclosure, the connection layer includes an insulating layer and a plurality of conductive bumps passing through the insulating layer. The second circuit of the power board is electrically connected to the first circuit of the signal board through the conductive bump.

Based on the above, in the design of the package carrier of the present disclosure, the connection layer is disposed between the signal board and the power board, wherein the power board is electrically connected to the signal board through the connection layer. In other words, the signal board and the power board are independent components, that is, the signal and the power supply are separated from each other, so that the optimized processes of the signal and the power supply may be applied effectively, and the manufacturing costs may be effectively reduced. Furthermore, the manufacturing method of the package carrier of the present disclosure is performed by connecting the provided power board to the signal board through the connection layer. Therefore, compared with the related art in which the signal and the power supply are manufactured in a mixed manner through same processes, the manufacturing method of the package carrier of the present disclosure has a simple manufacturing process and may effectively reduce the manufacturing cost, so as to optimize the different functions of each part. In addition, the chip package structure using the package carrier of the present disclosure may have a better yield and quality.

In order to make the above-mentioned features and advantages of the present disclosure more obvious and easy to understand, embodiments are given below and described in detail with reference to the attached drawings.

### BRIEF DESCRIPTION OF THE DRAWINGS

FIG. 1A to FIG. 1D are schematic cross-sectional views of a method for manufacturing a package carrier according to an embodiment of the present disclosure.

FIG. 1E is a schematic cross-sectional view of a chip package structure according to an embodiment of the present disclosure.

FIG. 2 is a schematic cross-sectional view of a power board according to an embodiment of the present disclosure.

FIG. 3A to FIG. 3D are schematic cross-sectional views of a method for manufacturing a package carrier according to another embodiment of the present disclosure.

FIG. 3E is a schematic cross-sectional view of a chip package structure according to another embodiment of the present disclosure.

FIG. 4A to FIG. 4D are schematic cross-sectional views of a method for manufacturing a package carrier according to another embodiment of the present disclosure.

FIG. 4E is a schematic cross-sectional view of a chip package structure according to another embodiment of the present disclosure.

### DESCRIPTION OF EMBODIMENTS

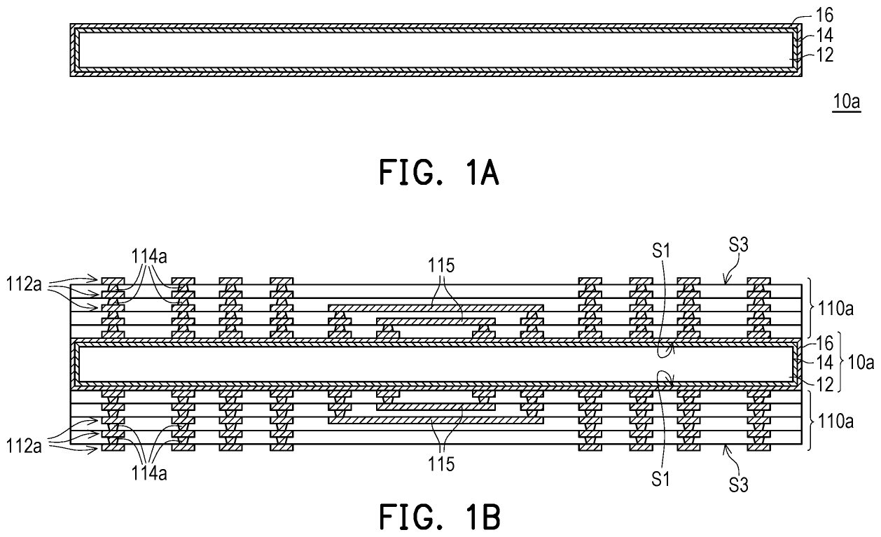

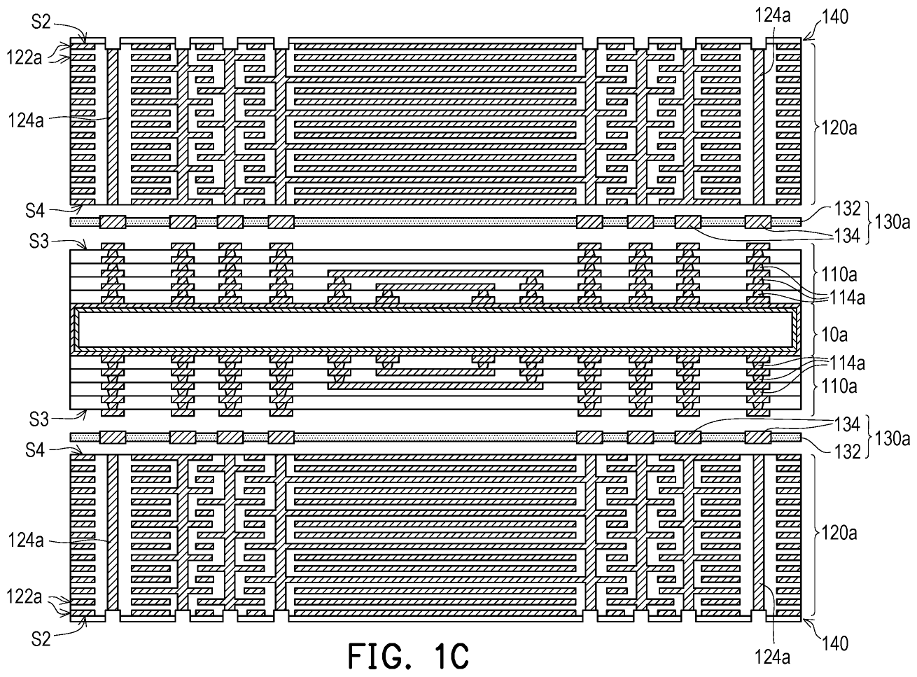

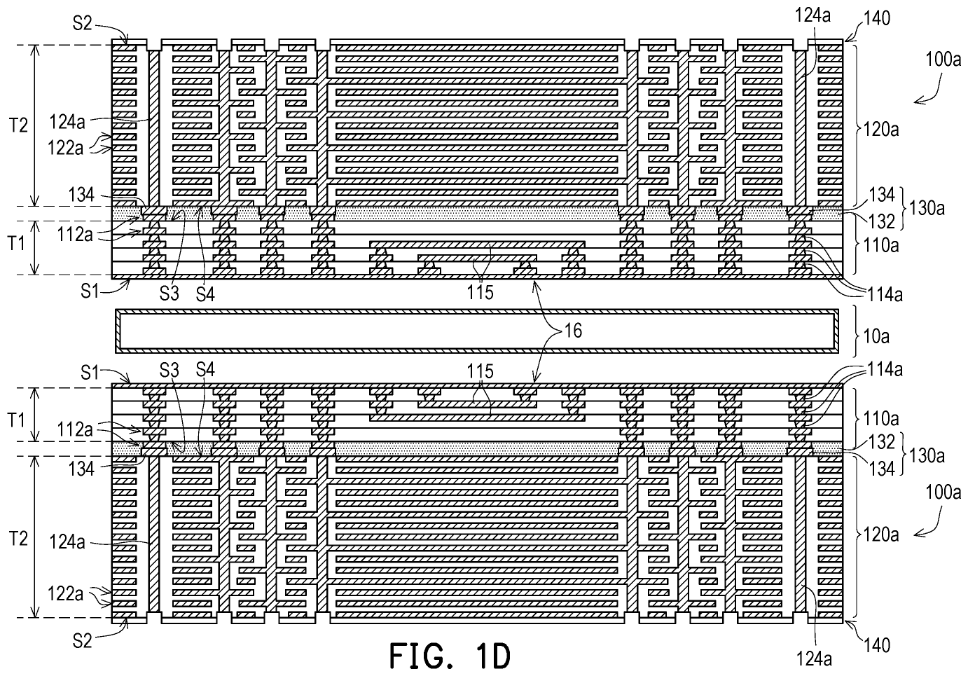

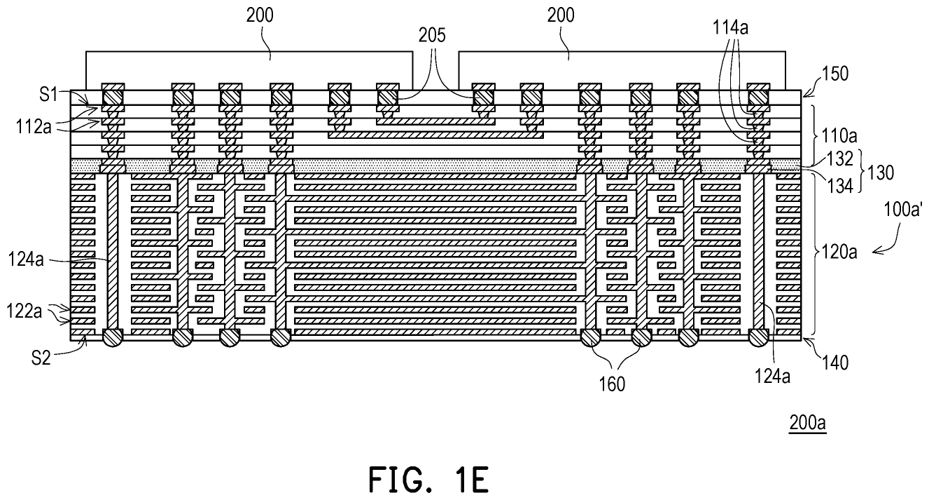

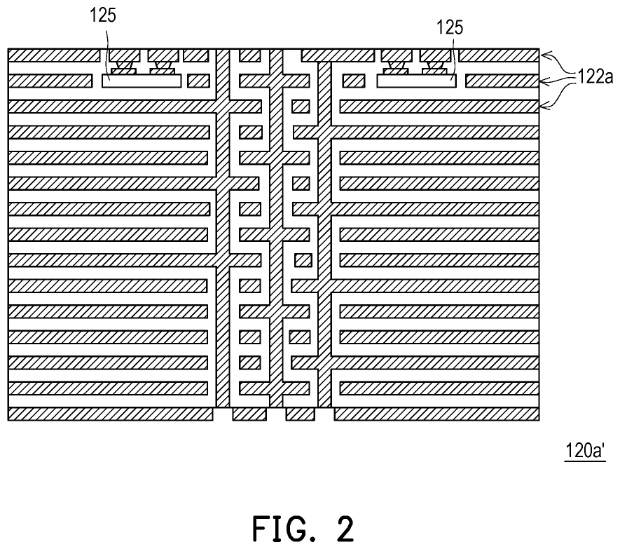

FIG. 1A to FIG. 1D are schematic cross-sectional views of a method for manufacturing a package carrier according to an embodiment of the present disclosure. FIG. 1E is a schematic cross-sectional view of a chip package structure according to an embodiment of the present disclosure.

Regarding the manufacturing method of the package carrier in this embodiment, first, please refer to FIG. 1A, a substrate 10a is provided. The substrate 10a includes a base 12, a stainless steel layer 14 and a metal layer 16. The stainless steel layer 14 is located on the base 12 and conformally covers the base 12. The metal layer 16 is formed on the stainless steel layer 14 and conformally covers the stainless steel layer 14. Here, the base 12 is, for example, a glass substrate or fiberglass resin. The stainless steel layer 14 is made of, for example, SUS 304 or other suitable models, wherein the thickness of the stainless steel layer 14 is, for example, between 0.05 microns and 1.5 microns. In other words, the stainless steel layer 14 may be regarded as a stainless steel film. The metal layer 16 is formed on the stainless steel layer 14 by, for example, electroplating, and the material of the metal layer 16 is, for example, copper, but the disclosure is not limited thereto.

Next, please refer to FIG. 1B, two signal boards 110a are formed on opposite sides of the substrate 10a, and are located on the metal layer 16. Each signal board 110a includes a plurality of first circuits 112a and a plurality of conductive blind vias 114a, wherein two adjacent layers of first circuits 112a are electrically connected through the conductive blind vias 114a. Each signal board 110a has a first side S1 and a third side S3 opposite to each other, wherein the first side is connected to the metal layer 16, and the third side S3 is relatively far away from the substrate 10a. Here, the signal board 110a has, for example, a five-layer circuit layer structure, in which the signal board 110a further includes a plurality of connection circuits 115 which respectively connect two adjacent first circuits 112a.

Next, please refer to FIG. 1C, two power boards 120a are provided, wherein each power board 120a includes a plurality of second circuits 122a and a conductive via 124a, and has a second side S2 and a fourth side S4 opposite to each other. Here, the second circuit 122a is, for example, a ground circuit or a power circuit. Next, a second solder mask 140 is formed on the second side S2 of each power board 120a that is relatively far away from each signal board 110a, and a portion of the second circuit 122a is exposed. Next, two connection layers 130a are provided between the third side S3 of each signal board 110a and the fourth side S4 of each power board 120a. Each connection layer 130a includes an insulating layer 132 and a plurality of conductive bumps 134 passing through the insulating layer 132, wherein the conductive bumps 134 are slightly higher than the insulating layer 132.

Next, please refer to FIG. 1C and FIG. 1D both. The two power boards 120a and the two connection layers 130a are laminated onto the substrate 10a by thermal pressing, wherein each power board 120a is electrically connected to each signal board 110a through each connection layer 130a. The second circuit 122a of the power board 120a may be electrically connected to the first circuit 112a of the signal board 110a through the conductive bumps 134. Here, the line width of each first circuit 112a is less than the line width of each second circuit 122a. A first thickness T1 of the signal board 110a is less than a second thickness T2 of the power board 120a. In an embodiment, the first thickness T1 is, for example, 100 micrometers (μm), and the second thickness T2 is, for example, 1.5 millimeters (mm), but the disclosure is not limited thereto.

The thickness T2 of the power board 120a is at least four times the thickness T1 of the signal board 110a or more. In an embodiment, the number of circuit layers of the power board 120a is, for example, 15 layers, and the number of circuit layers of the signal board 110a is, for example, 9 layers, but the disclosure is not limited thereto.

Thereafter, please refer to FIG. 1D. The substrate 10a and the two signal boards 110a are separated from each other to form two package carriers 100a that are separated from each other. Here, each package carrier 100a includes a signal board 110a, a power board 120a and a connection layer 130a. At this point, the production of the package carrier 100a has been completed.

Structurally, please refer to FIG. 1D again. The package carrier 100a includes a signal board 110a, a power board 120a and a connection layer 130a. The signal board 110a includes a first circuit 112a. The power board 120a includes a second circuit 122a. The line width of each first circuit 112a is less than the line width of each second circuit 122a, and the first thickness T1 of the signal board 110a is less than the second thickness T2 of the power board 120a. The connection layer 130a is disposed between the signal board 110a and the power board 120a, wherein the power board 120a is electrically connected to the signal board 110a through the connection layer 130a. Here, the connection layer 130a includes an insulating layer 132 and a conductive bump 134 passing through the insulating layer 132. The second circuit 122a of the power board 120a may be electrically connected to the first circuit 112a of the signal board 110a through the conductive bump 134. The thickness T2 of the power board 120a is at least four times the thickness T1 of the signal board 110a or more. In this embodiment, the signal board 110a may further include connection circuits 115 that respectively connect two adjacent first circuits 112a. In addition, the package carrier 100a further includes a second solder mask 140 disposed on the second side S2 of the power board 120a that is relatively far away from the signal board 110a, and exposes a portion of the second circuit 122a.

Next, please refer to FIG. 1E. In another embodiment, the manufacturing method of the package carrier may further include forming a first solder mask 150 on the first side S1 of the signal board 110a relatively away from the power board 120a, and exposes a portion of the first circuit 112a. Next, the manufacturing method of the package carrier of this embodiment may further include forming a plurality of solder balls 160 on the second side S2 of the power board 120a that is relatively far away from the signal board 110a, and connected to a portion of the second circuit 122a that is exposed by the second solder mask 140. At this point, the production of package carrier 100a′ has been completed. Moreover, the chip 200 may be disposed on the signal board 110a and electrically connected to the first circuit 112a exposed by the first solder mask 150 through the plurality of solder balls 205, thereby completing the production of the chip package structure 200a. Therefore, structurally, the chip package structure 200a includes the package carrier 100a′ and the chip 200, wherein the chip 200 is disposed on the signal board 110a and is electrically connected to the first circuit 112a. Here, the chip 200 is electrically connected to the first circuit 112a of the signal board 110a through flip-chip bonding. The conductive via 124a of the power board 120a is electrically connected to the signal board 110a through the conductive bump 134 of the connection layer 130a, so as to be directly connected to the chip 200 through the stacked blind via (i.e., the stacked conductive blind via 114a) in the signal board 110a, thereby improving the efficiency and stability of power supply.

In short, since the connection layer 130a of this embodiment is disposed between the signal board 110a and the power board 120a, wherein the conductive via 124a of the power board 120a is electrically connected to the stacked blind via (i.e., the stacked conductive blind via 114a) in the signal board 110a through the connection layer 130a and directly connected to the chip 200, thereby enhancing performance and stability of power supply. That is to say, the signal board 110a and the power board 120a are independent components, that is, the signal and the power supply are separated from each other, so that the optimized processes of the signal and the power supply may be applied effectively, and the manufacturing costs may be effectively reduced. Furthermore, in the manufacturing method of the package carrier in this embodiment, since the provided power board 120a is connected to the signal board 110a through the connection layer 130a, compared with the related art in which the signal and the power supply are manufactured in a mixed manner through same processes, the manufacturing method of the package carrier in the embodiment of the present disclosure has a simple manufacturing process and may effectively reduce the manufacturing cost, so as to optimize the different functions of each part. In addition, since the manufacturing method of the package carrier in this embodiment is able to manufacture two package carriers simultaneously, the manufacturing method of the package carrier of the disclosure has the advantages of saving process time and increasing production capacity. Additionally, the chip package structure 200a using the package carrier 100a of this embodiment may have a better yield and quality.

It must be noted here that the following embodiments adopt the component numbers and part of the content of the previous embodiments, wherein the same numbers are used to represent the same or similar components, and the description of the same technical content is omitted. For descriptions of omitted parts, reference may be made to the foregoing embodiments and will not be repeated in the following embodiments.

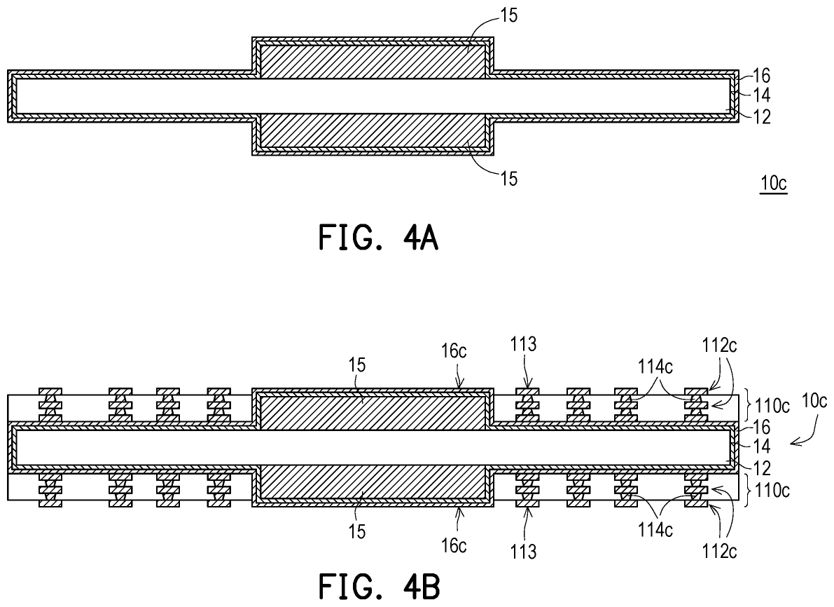

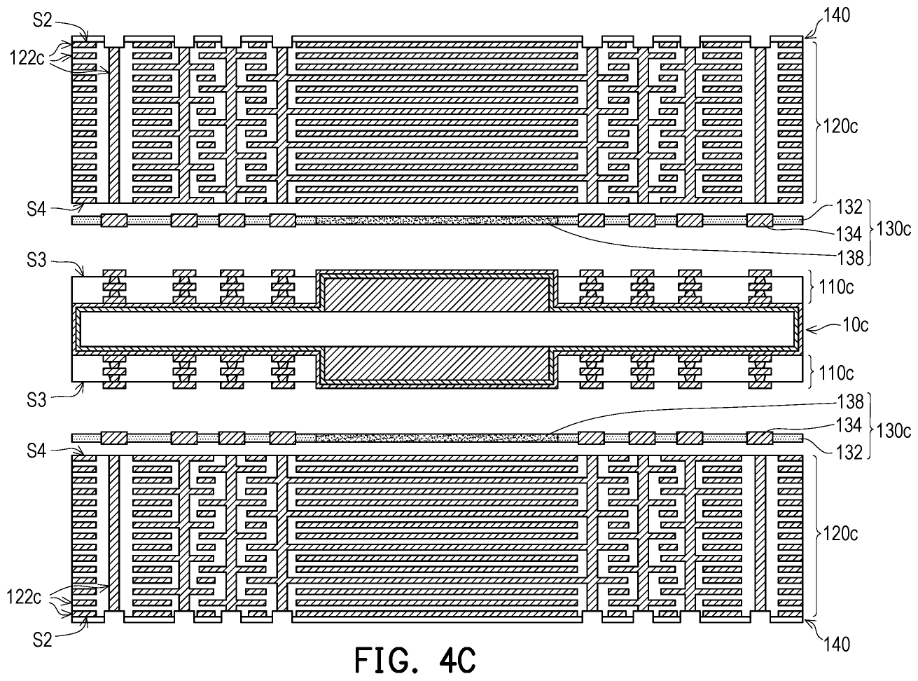

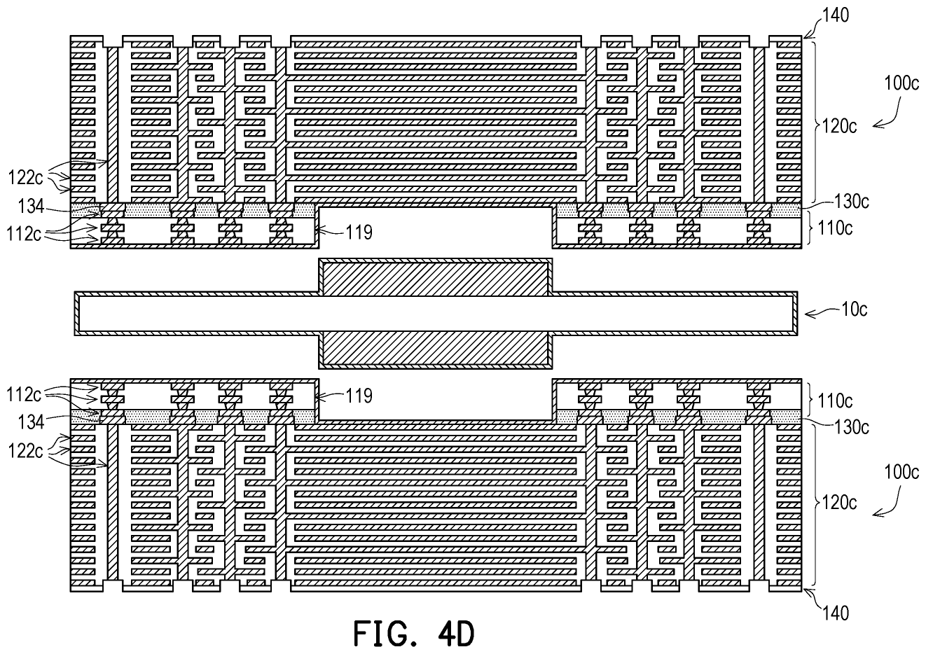

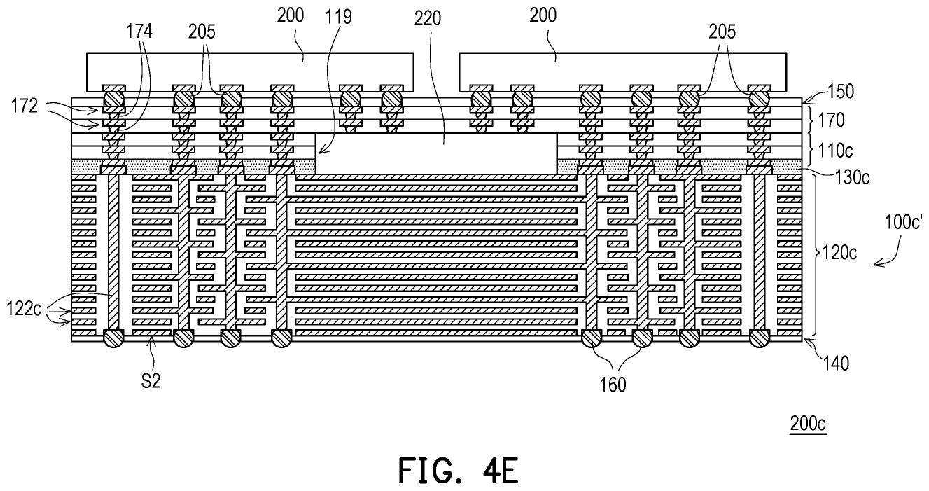

FIG. 2 is a schematic cross-sectional view of a power board according to an embodiment of the present disclosure. Please refer to FIG. 1C and FIG. 2 at the same time. The power board 120a′ of this embodiment is similar to the power board 120a mentioned above. The difference between the two is that in this embodiment, when performing the step of FIG. 1C, that is, before the power board 120a and the connection layer 130a are laminated onto the substrate 10a, a plurality of capacitors 125 are formed and embedded in the power board 120a′, and are electrically connected to the corresponding power board 120a′. That is to say, the subsequently formed package carrier further includes a plurality of capacitors 125, which are embedded in the power board 120a′ and are electrically connected to the power board 120a′. The above process requires making a cavity 119 as shown in FIG. 4D in the power board 120a′. After the capacitor 125 is placed in the opening, the uppermost insulating layer and conductive layer of the second circuit 122a are laminated together and connected to the capacitor 125 through the blind via that is made through laser. The function of this capacitor is to maintain the stability of the power supply during electrical switching in digital circuits.

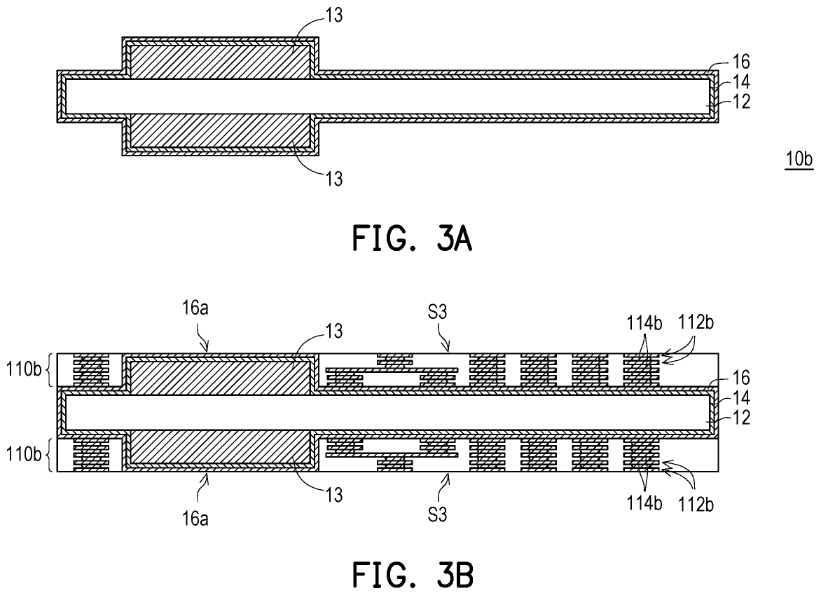

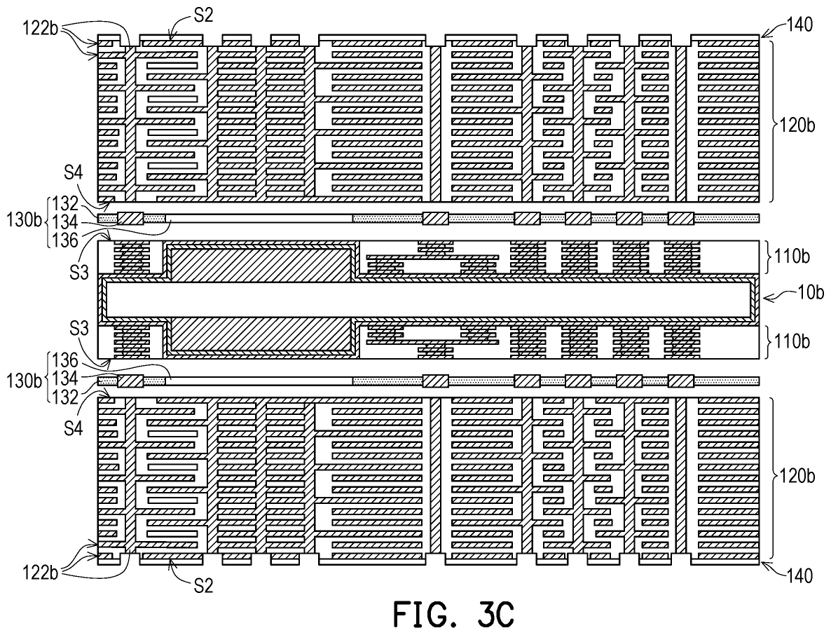

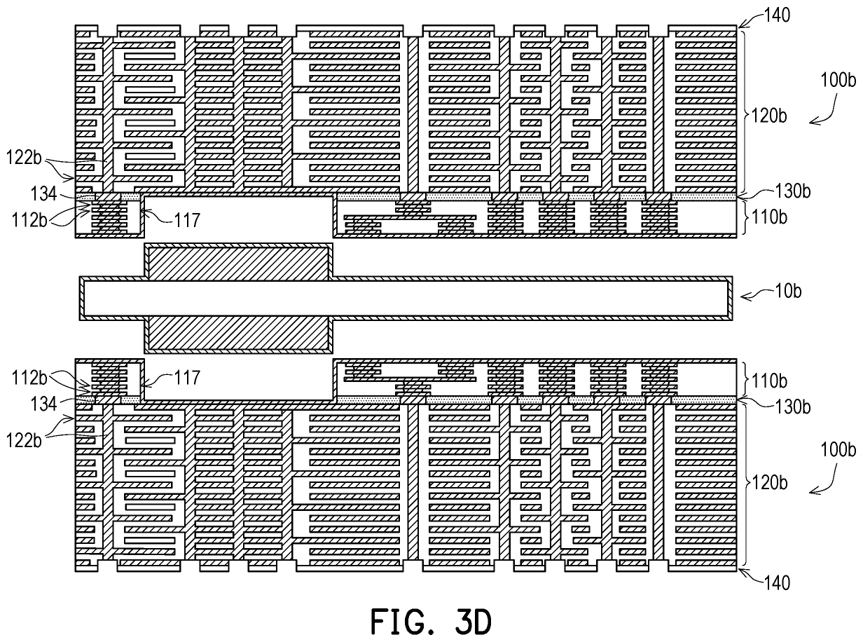

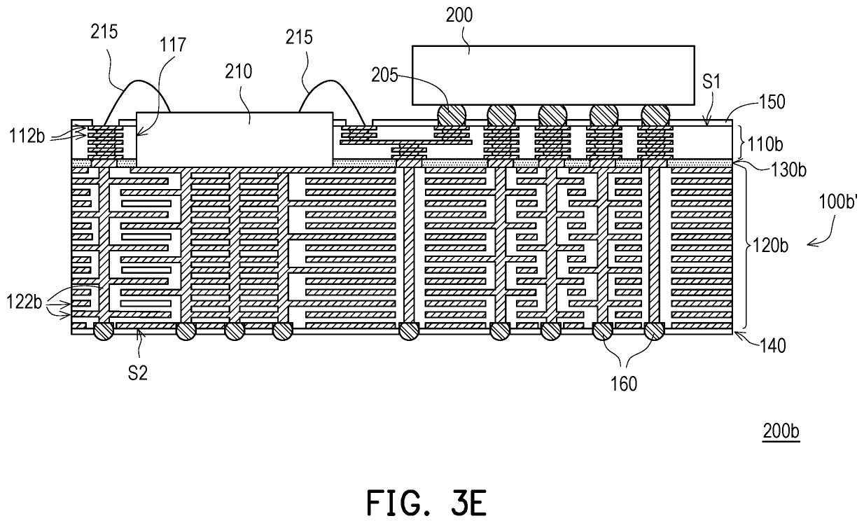

FIG. 3A to FIG. 3D are schematic cross-sectional views of a method of manufacturing a package carrier according to another embodiment of the present disclosure. FIG. 3E is a schematic cross-sectional view of a chip package structure according to another embodiment of the present disclosure. Please refer to FIG. 1A and FIG. 3A at the same time. The manufacturing method of the package carrier in this embodiment is similar to the manufacturing method of the above-mentioned package carrier. The difference between the two is that in this embodiment, the base 12 of the substrate 10b further includes two protrusions 13, wherein two protrusions 13 are respectively located on opposite sides of the base 12. The material of the protrusion 13 is different from the material of the base 12. The material of the protrusion 13 is copper, for example, but the disclosure is not limited thereto.

Next, please refer to FIG. 3B. Two signal boards 110b are formed on opposite sides of the substrate 10b and are located on the metal layer 16. Each signal board 110b includes a plurality of first circuits 112b and a plurality of conductive blind vias 114b, wherein two adjacent layers of first circuits 112b are electrically connected through the conductive blind vias 114b. Here, the third side S3 of each signal board 110b is aligned with the surface 16a of the metal layer 16.

Next, please refer to FIG. 3B and FIG. 3C simultaneously. Two power boards 120b are provided, wherein each power board 120b includes a plurality of second circuits 122b. Here, the second circuit 122b is, for example, a ground circuit or a power circuit. Next, a second solder mask 140 is formed on the second side S2 of each power board 120b that is relatively far away from each signal board 110b, and exposes a portion of the second circuit 122b. Next, two connection layers 130b are provided between the third side S3 of each signal board 110b and the fourth side S4 of each power board 120b. Each connection layer 130b includes an insulating layer 132, a plurality of conductive bumps 134 passing through the insulating layer 132, and a release film 136. The conductive bump 134 is slightly higher than the insulating layer 132, and the position of the release film 136 corresponds to the position of the protrusion 13.

Next, please refer to FIG. 3C and FIG. 3D both. The two power boards 120b and the two connection layers 130b are laminated onto the substrate 10b, wherein each power board 120b is electrically connected to each signal board 110b through each connection layer 130b. The second circuit 122b of the power board 120b is electrically connected to the first circuit 112b of the signal board 110b through the conductive bumps 134.

Thereafter, please refer to FIG. 3D, the substrate 10b and the two signal boards 110b are separated from each other to form a cavity 117 penetrating each signal board 110b, wherein the cavity 117 exposes the release film 136 of the connection layer 130b. Next, the release film 136 is removed to form two package carriers 100b that are separated from each other. Each package carrier 100b includes a signal board 110b with a cavity 117, a power board 120b and a connection layer 130b. At this point, the production of the package carrier 100b has been completed.

Next, please refer to FIG. 3E. In another embodiment, the manufacturing method of the package carrier may further include forming a first solder mask 150 on the first side S1 of the signal board 110b relatively far away from the power board 120b, and exposes a portion of the first circuit 112b. Next, the manufacturing method of the package carrier of this embodiment may further include forming a plurality of solder balls 160 on the second side S2 of the power board 120b that is relatively far away from the signal board 110b, and connecting to a portion of the second circuit 122b that is exposed by the second solder mask 140. At this point, the production of package carrier 100b′ has been completed. Moreover, the chip 200 may be disposed on the signal board 110b and electrically connected to the first circuit 112b exposed by the first solder mask 150 through the plurality of solder balls 205, and the chip 210 may be disposed in the cavity 117, and is electrically connected to the first circuit 112b through a plurality of wires 215. At this point, the production of the chip package structure 200b may be completed. In short, the chip package structure 200b of this embodiment is a structure including a multi-chip module (MCM) and a ball grid array (BGA) substrate.

FIG. 4A to FIG. 4D are schematic cross-sectional views of a method for manufacturing a package carrier according to another embodiment of the present disclosure. FIG. 4E is a schematic cross-sectional view of a chip package structure according to another embodiment of the present disclosure. Please refer to FIG. 1A and FIG. 4A at the same time. The manufacturing method of the package carrier in this embodiment is similar to the manufacturing method of the above-mentioned package carrier. The difference between the two is that in this embodiment, the base 12 of the substrate 10c includes two protrusions 15, wherein the two protrusions 15 are respectively located on opposite sides of the base 12. The material of the protrusion is different from the material of the base 12. The material of the protrusion 15 is copper, for example, but the disclosure is not limited thereto. In an embodiment, the protrusion 15 may be, for example, a copper pillar, and a height thereof may be, for example, 60 microns.

Next, please refer to FIG. 4B, two signal boards 110c are formed on opposite sides of the substrate 10c, and are located on the metal layer 16. Each signal board 110c includes a plurality of first circuits 112c and a plurality of conductive blind vias 114c, wherein two adjacent layers of first circuits 112c are electrically connected through the conductive blind via 114c. Here, the surface 113 of the outermost first circuit 112c of each signal board 110c is approximately aligned with the surface 16c of the metal layer 16. In an embodiment, the signal board 110c has three circuit layers, wherein the thickness of the signal board 110c is, for example, 30 microns, but the disclosure is not limited thereto.

Next, please refer to FIG. 4B and FIG. 4C simultaneously. Two power boards 120c are provided, wherein each power board 120c includes a plurality of second circuits 122c. Here, the second circuit 122c is, for example, a ground circuit or a power circuit. Next, a second solder mask 140 is formed on the second side S2 of each power board 120c that is relatively far away from each signal board 110c, and exposes a portion of the second circuit 122c. Next, two connection layers 130c are provided between the third side S3 of each signal board 110c and the fourth side S4 of each power board 120c. Each connection layer 130c includes an insulating layer 132, a plurality of conductive bumps 134 passing through the insulating layer 132, and a release film 138. The conductive bump 134 is slightly higher than the insulating layer 132, and at this point, the position of the release film 138 may correspond to the position of the protrusion 15.

Next, please refer to FIG. 4C and FIG. 4D at the same time. The two power boards 120c and the two connection layers 130c are laminated onto the substrate 10c by thermal pressing, wherein each power board 120c is electrically connected to each signal board 110c through each connection layer 130c. The second circuit 122c of the power board 120c is electrically connected to the first circuit 112c of the signal board 110c through the conductive bump 134.

Thereafter, please refer to FIG. 4C and FIG. 4D at the same time. The substrate 10c and the two signal boards 110c are separated from each other to form a cavity 119 penetrating each signal board 110c, wherein the cavity 119 exposes the release film 138 of the connection layer 130c. Next, the release film 138 is removed to form two package carriers 100c that are separated from each other. Each package carrier 100c includes a signal board 110c with a cavity 119, a power board 120c and a connection layer 130c. At this point, the production of the package carrier 100c has been completed.

Next, please refer to FIG. 4E. In an embodiment, the chip 220 may be disposed in the cavity 119. Next, an outer circuit layer 170 may also be formed to cover the chip 220 and the signal board 110c. The outer circuit layer 170 includes a plurality of outer circuits 172 and a plurality of conductive blind vias 174. Two adjacent layers of outer circuits 172 are electrically connected through the conductive blind vias 174, and the conductive blind vias 174 are also electrically connected to the chip 220 and the outer circuit 172. Furthermore, the manufacturing method of the package carrier may further include forming the first solder mask 150 on the outer circuit layer 170 and exposing a portion of the outer circuit layer 172. Next, the manufacturing method of the package carrier this embodiment may also include forming a plurality of solder balls 160 on the second side S2 of the power board 120c that is relatively far away from the signal board 110c, and connecting to a portion of the second circuit 122c that is exposed by the second solder mask 140. At this point, the production of the package carrier 100c′ with the embedded chip 220 has been completed. Moreover, the chip 200 may be disposed on the outer circuit layer 170 on the signal board 110c, and is electrically connected to the outer circuit 172 exposed by the first solder mask 150 through a plurality of solder balls 205. At this point, the production of the chip package structure 200c may be completed.

To sum up, in the design of the package carrier of the present disclosure, the connection layer is disposed between the signal board and the power board, and the power board is electrically connected to the signal board through the connection layer. In other words, the signal board and the power board are independent components, that is, the signal and the power supply are separated from each other, so that the optimized processes of the signal and the power supply may be applied effectively, and the manufacturing costs may be effectively reduced. Furthermore, the manufacturing method of the package carrier of the present disclosure is performed by connecting the provided power board to the signal board through the connection layer. Therefore, compared with the related art in which the signal and the power supply are manufactured in a mixed manner through same processes, the manufacturing method of the package carrier of the present disclosure has a simple manufacturing process and may effectively reduce the manufacturing cost, so as to optimize the different functions of each part. In addition, the chip package structure using the package carrier of the present disclosure may have a better yield and quality.

Although the present disclosure has been disclosed above through embodiments, it is not intended to limit the present disclosure. Anyone with ordinary knowledge in the technical field can make some modifications and refinement without departing from the spirit and scope of the present disclosure. Therefore, the scope to be protected by the present disclosure shall be determined by the appended claims.

What is claimed is:

1. A package carrier, comprising:
a signal board comprising a plurality of first circuits;
a power board comprising a plurality of second circuits, wherein a line width of each of the plurality of first circuits is less than a line width of each of the plurality of second circuits, and a first thickness of the signal board is less than a second thickness of the power board; and
a connection layer disposed between the signal board and the power board, wherein the power board is electrically connected to the signal board through the connection layer.

2. The package carrier according to claim 1, wherein the signal board has a set of stacked vias, which penetrates the signal board and is connected to the connection layer.

3. The package carrier according to claim 1, wherein the signal board further comprises a plurality of connection circuits respectively connecting the two adjacent first circuits.

4. The package carrier according to claim 1, further comprising:
a plurality of capacitors, which are embedded in the power board and are electrically connected to the power board.

5. The package carrier according to claim 1, wherein a thickness of the power board is at least four times a thickness of the signal board or more.

6. The package carrier according to claim 1, wherein the connection layer comprises an insulating layer and a plurality of conductive bumps passing through the insulating layer, the plurality of second circuits of the power board is electrically connected to the plurality of first circuits of the signal board through the plurality of conductive bumps.

7. A manufacturing method of a package carrier, comprising:
providing a substrate comprising a base, a stainless steel layer and a metal layer, wherein the stainless steel layer is located on the base and conformally covers the base, the metal layer is formed on the stainless steel layer and conformally covers the stainless steel layer;
forming two signal boards on opposite sides of the substrate, and each of the signal boards comprising a plurality of first circuits;
providing two power boards, each of the power boards comprising a plurality of second circuits;
providing two connection layers between each of the signal boards and each of the power boards;
laminating the two power boards and the two connection layers onto the substrate, wherein each of the power boards is electrically connected to each of the signal boards through each of the connection layers, a line width of each of the plurality of first circuits is less than a line width of each of the plurality of second circuits, a first thickness of the signal board is less than a second thickness of the power board; and
separating the substrate from the two signal boards to form two package carriers that are separated from each other, wherein each of the package carriers comprises one of the two signal boards, one of the two power boards, and one of the two connection layers.

8. The manufacturing method of the package carrier according to claim 7, wherein the base of the substrate comprises two protrusions, the two protrusions are respectively located on opposite sides of the base, when the substrate and the two signal boards are separated from each other, a cavity that penetrates through each of the signal boards is formed, and the cavity exposes a portion of each of the connection layers.

9. The manufacturing method of the package carrier according to claim 7, wherein the signal board further comprises a plurality of connection circuits which respectively connect the two adjacent first circuits.

10. The manufacturing method of the package carrier according to claim 7, further comprising:
forming a plurality of capacitors embedded in each of the power boards before laminating the two power boards and the two connection layers onto the substrate, wherein the plurality of capacitors are electrically connected to each of the corresponding power boards.

11. The manufacturing method of the package carrier according to claim 7, wherein a thickness of the power board is at least four times a thickness of the signal board or more.

12. The manufacturing method of the package carrier according to claim 7, wherein each of the connection layers comprises an insulating layer and a plurality of conductive bumps passing through the insulating layer, the plurality of second circuits of the power board are electrically connected to the plurality of first circuits of the signal board through the plurality of conductive bumps.

13. The manufacturing method of the package carrier according to claim 8, wherein each of the connection layers comprises an insulating layer, a plurality of conductive bumps passing through the insulating layer, and a release film, the plurality of second circuits of the power board are electrically connected to the plurality of first circuits of the signal board through the plurality of conductive bumps, a position of the release film respectively corresponds to a position of each of the protrusions, when the substrate and the two signal boards are separated from each other, the cavity correspondingly exposes the release film of each of the connection layers.

14. A chip package structure, comprising:
a package carrier comprising:
a signal board comprising a plurality of first circuits;
a power board comprising a plurality of second circuits, wherein a line width of each of the plurality of first circuits is less than a line width of each of the plurality of second circuits, and a first thickness of the signal board is less than a second thickness of the power board; and
a connection layer disposed between the signal board and the power board, wherein the power board is electrically connected to the signal board through the connection layer; and
at least one chip disposed on the signal board and electrically connected to the plurality of first circuits.

15. The chip package structure according to claim 14, wherein the signal board has a set of stacked vias, which penetrates the signal board and is connected to the connection layer.

16. The chip package structure according to claim 15 wherein the at least one chip comprises a first chip and a second chip, the first chip is disposed in the set of stacked vias and is electrically connected to the plurality of first circuits through a plurality of wires, the second chip is disposed on the signal board and is electrically connected to the plurality of first circuits through a plurality of solder balls.

17. The chip package structure according to claim 15, wherein the at least one chip comprises a first chip and two second chips, the package carrier further comprises an outer circuit layer, the first chip is disposed in the set of stacked vias, and the outer circuit layer covers the first chip and the signal board, the two second chips are disposed on the signal board and are electrically connected to the first chip through a plurality of solder balls.

18. The chip package structure according to claim 14, wherein the signal board further comprises a plurality of connection circuits which respectively connect the two adjacent first circuits.

19. The chip package structure according to claim 18, wherein the at least one chip is disposed on the signal board and is electrically connected to the plurality of first circuits through a plurality of solder balls.

20. The chip package structure according to claim 14, wherein a thickness of the power board is at least four times a thickness of the signal board or more.

21. The chip package structure according to claim 14, wherein the connection layer comprises an insulating layer and a plurality of conductive bumps passing through the insulating layer, the plurality of second circuits of the power board are electrically connected to the plurality of first circuits of the signal board through the plurality of conductive bumps.
